(19) United States
(12) Patent Application Publication
(10) Pub. No.: US 2004/0192234 A1
(43) Pub. Date: Sep. 30, 2004

(54) Linear Amplification by synchronized chaotic oscillation

(76) Inventors: Chance Michael Glenn SR., Columbia, MD (US); Scott T. Hayes, New Creek, WV (US)

Correspondence Address: PATTON BOGGS LLP, ATTORNEYS AT LAW, 2550 M Street, NW, Washington, DC, 20037-1350, US

(21) Appl. No.: 10/400,927

(22) Filed: Mar. 28, 2003

(51) Int. Cl. H04B 1/04; H03G 3/20

(52) U.S. Cl. 455/127.1; 455/91; 330/137; 330/127

(57) ABSTRACT

An amplifier for arbitrary waveforms, including a chaotic oscillator circuit having a coupling element for receiving an information signal. A load is connected to the chaotic oscillator circuit. The oscillation of the chaotic oscillator circuit synchronizes to the information signal and delivers an output signal substantially identical to the information signal and dissipates a power in the load amplified with respect to the information signal. The chaotic oscillator optionally uses an active element such that when synchronized it is in a non-linear operating region. Optionally, the error between the information signal and output voltage is minimized by controlling the volume of the chaotic oscillator in response to the error.

### FIELD OF THE INVENTION

The present invention relates to the amplification of electronic signals and, more particularly, to linear amplification of signals having arbitrary waveforms by synchronization of a chaotic oscillator.

### DESCRIPTION OF THE BACKGROUND

In the electrical and telecommunication arts, amplifiers are devices that receive an electrical signal having a first power and output, signal of the same waveform as the input, but at a significantly higher current and, therefore, capable of delivering a power significantly higher than the first power. Early amplifiers used vacuum tubes as a basic building block, each tube acting as an electric current valve, by using a low power signal to control a much higher electric power flow between the tube's anode and cathode. Ideally, the current flowing between the anode and the cathode is perfectly proportional to the control signal. In other words, for most applications a sought-after transfer function for a vacuum tube is linear, the output being exactly a fixed multiple of the input. The actual transfer function of a vacuum tube, however, is not linear. The non-linearity therefore had to be compensated. Various compensation schemes and methods were developed, including, but not limited to, stringent biasing requirements of the tube elements, and limiting the tube's voltage swings to limit operation to the tube's most linear region, and use of feedback techniques. These compensation schemes are well-known and readily found in textbooks.

Semiconductor transistors have essentially replaced vacuum tubes as the building block of electrical amplifiers. The size, weight, power consumption and cost of transistors are markedly superior to vacuum tubes. In fact, without transistors most present wireless communication systems would likely not exist.

However, transistors share one significant shortcoming with vacuum tubes, namely, their transfer function is not linear. For this reason, transistor-based amplifiers generally include various compensation methods, including selection of biasing point.

Designers typically strive for linear amplifiers because the general objective of an amplifier is to generate an output that is an exact, undistorted, replica of the input signal but at a higher power. The power is needed, for example, to broadcast the signal from an antenna over a desired distance, or to transmit a signal over a transmission line, or to drive a power consumptive load such as an audio speaker. Linearity is required because, at least for conventional information-carrying signaling methods, the waveform of the signal carries information. If the waveform is distorted information is degraded or lost, or the information carrying capacity of the signal is lowered. An example reason for the degradation or loss of information, the channel's carrying capacity is that typical information-carrying signals consist of, or can be represented as, a weighted plurality of sinusoids. As known in the electrical arts, when a sinusoid is amplified or repeated by a non-linear device the output includes not only the fundamental frequency of the input, but also harmonics of that input. The harmonics degrade the signal and cause interference between signals occupying proximal bands of the frequency spectrum.

The general design philosophy in the art of electronic amplifiers is therefore to obtain a linear amplifier, or as linear as required, using a circuit based on transistors, which are inherently non-linear. This conventional design philosophy, however, faces at least one well-known dilemma. This dilemma is that biasing and interconnecting transistors to obtain a more linear transfer function typically lowers the efficiency of the amplifier.

For example, the traveling wave tubes (TWTs) in satellites must be operated in a nonlinear mode, otherwise the efficiency is too poor for the overall system to be cost effective. This incurs a performance cost, as the signal constellations generated by TWTs are severely distorted. This poses substantial problems because communication signal theory, and its practical implementation in existing technology, is largely a linear art. Conventional amplifiers employing nonlinear devices distort the linear signals from their ideal form. Most communication systems, such as cellular telephones, cannot tolerate the signal degradation and out-of-band interference that would result from employing non-linear transistor modes. The search for methods to deal with this problem effectively is ongoing.

### SUMMARY OF THE EMBODIMENTS

The present apparatus and methods advances the art and provides functions, aspects and features which include, for example, substantially eliminating the inherent linearity-efficiency tradeoff of existing amplifier circuits, and removing the requirement for, and the constraints imposed by, prior art design methodologies, structures and implementations of linear amplifies.

An example embodiment includes a power supply, and a chaotic oscillator power circuit connected to the power supply. The chaotic oscillator power circuit includes a coupling element for receiving an externally generated information signal. A load is connected to, or is an element within, the chaotic oscillator power circuit. The power chaotic circuit and the receiving terminal are arranged and constructed such that, concurrent with the information signal delivered to the receiving terminal being switched off or below a predetermined input voltage envelope, the energy state of the powered element oscillates according to a chaotic system dynamic. When the information signal is switched on or is above the predetermined input voltage envelope, the voltage on the coupling element perturbs the oscillation of the chaotic oscillator power circuit. The coupling element is arranged such that the perturbation causes the chaotic oscillator power circuit to source an output voltage substantially identical to the information signal. The output voltage delivers a power to the load that is amplified from the power delivered by the information signal.

In a further aspect, the power chaotic circuit includes at least one circuit element, the circuit element having a substantially linear V-I region and a substantially non-linear V-I region, the power chaotic circuit and its active circuit element being constructed and arranged such that the active element operates, over a time average, in its non-linear region a substantial percentage of that time.

In a still further aspect, the circuit element is an active circuit element, the active circuit element having a transfer control terminal, a first current terminal and a second current terminal. The control terminal is connected to receive a transfer signal representing at least part of instant value of the state vector of the power chaotic circuit.

In this further aspect, the power chaotic circuit and the active circuit element are constructed and arranged such that the active circuit element is in its non-linear region as the information signal perturbs the chaotic oscillator power circuit to source an output voltage substantially identical to the information signal.

In a still further aspect, the power chaotic circuit includes a circuit for detecting an energy state of at least one element of the power chaotic oscillator, and a parameter control signal circuit for generating a parameter control signal based on the detected at least one energy state. The power chaotic oscillator circuit includes a controllable element, the controllable element having an electrical characteristic based, at least in part, on the parameter control signal. The controllable element is constructed and arranged within the power chaotic circuit such that the relationship between the controllable element's electrical characteristic and the oscillation dynamic of the power chaotic circuit is in accordance with a predetermined relationship.

In a still further aspect, the parameter control signal circuit and the controllable element are constructed and arranged, and the predetermined relationship is defined, such that the oscillation dynamic of the power chaotic circuit seeks a state maximizing the power added efficiency of the amplifier. The power added efficiency consists essentially of the power delivered by the power supply to the power chaotic circuit divided by the sum of the power dissipated by the powered element and the power delivered to the power chaotic circuit by the information signal.

An objective obtained with an amplifier in accordance with this description is the elimination of the linearity compensation schemes and hardware required for conventional linear element amplifier circuits.

Another objective obtained with an amplifier in accordance with this description is the elimination of the conventional amplifier requirement of selecting active circuit elements, and biasing such elements, to operate within the elements' linear regions.

These and/or other objects, features and advantage will become more apparent to, and better understood by those skilled in the relevant art from the following further detailed description of the preferred embodiments of the invention taken with reference to the accompanying drawings, in which like features are identified by like reference numerals.

### BRIEF DESCRIPTION OF THE DRAWINGS

FIG. 1 depicts a high level block diagram of a described synchronous dynamic amplifier;

FIG. 2 depicts a circuit schematic for an example synchronous dynamic amplifier according to the FIG. 1 example block diagram, having a non-driven chaotic orbit frequency of approximately 150 MHz;

FIG. 3 shows a two-dimensional projection of the chaotic system dynamic produced by an example implementation of the FIG. 2 power chaotic oscillator portion of the FIG. 2 synchronous dynamic amplifier using a time delay embedding of the output voltage Vout(t);

FIG. 4 shows the frequency spectrum of the Vout(t) component of the FIG. 3 dynamic oscillation, illustrating the broad frequency content indicative of chaotic behavior;

FIG. 5 shows the frequency spectrum of the Vout(t) component when switch SW1 is closed and a 150 MHz sine wave is the IN(t) connected to the FIG. 2 circuit;

FIG. 6 depicts a variation of the attractor volume as the capacitor C2tune of the FIG. 2 circuit is changed;

FIG. 7 illustrates a relation of power gain of the FIG. 1 synchronous dynamic amplifier, with the FIG. 2 example chaotic oscillator power circuit, with respect to change of a tuning capacitance C2tune;

FIG. 8 shows a surface map illustrating the power added efficiency for a range of peak-to-peak input voltages and a range of tuning capacitance values;

FIG. 9 shows an example chaotic oscillator power circuit 2B, based on the FIG. 2 circuit 2A, for automatically adjusting the C2tune capacitance and maximizing the PAE over a range of IN(t) envelopes;

FIG. 10 shows another example of a synchronous dynamic amplifier according to FIG. 1, having a free-running oscillation of approximately 2 MHz;

FIG. 10A shows a two-dimensional projection of the chaotic oscillation exhibited by the FIG. 10 circuit;

FIG. 10B shows the frequency spectrum of the emitter voltage of the FIG. 10 synchronous dynamic amplifier in free-running oscillation;

FIGS. 11A through 11D illustrate an example of a standard-type GSM waveform, where 11A and 11B depict, respectively, the in-phase and quadrature baseband components, 11C depicts the modulated carrier, and 11D depicts the power spectrum;

FIGS. 12A through 12C graphically depict, respectively, a computer simulation of the FIG. 10 example synchronous dynamic amplifier receiving the signal of FIGS. 11A through 11D, the amplified output signal appearing on the load, and the error signal;

FIG. 13 shows a schematic diagram of a 850 MHz example high-frequency, Colpitts type, chaotic power oscillator; and

FIG. 14 shows the DC I-V characteristics for the high-frequency HBT used to model the FIG. 11 850 MHz circuit.

### DETAILED DESCRIPTION OF THE EMBODIMENTS

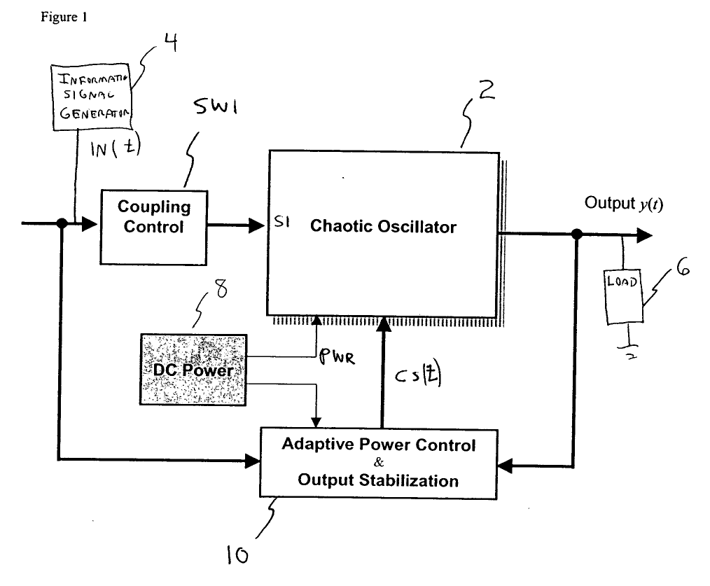

FIG. 1 is a high level functional block diagram of an example linear-transfer chaotic oscillator based amplifier. The amplifier exemplified by the FIG. 1 block diagram is referenced in this description as the “synchronous dynamic amplifier.” The FIG. 1 functional block diagram is arranged for one of skill in the pertinent arts to reference while reading this description, to assist in understanding the operation of the described chaotic oscillator based amplifier. It is to be understood that the FIG. 1 functional block diagram is arranged according to function, and does not necessarily represent any preferred modularity or arrangement of hardware. Example circuit diagrams and hardware implementations are described in reference to further figures.

Referring to FIG. 1, the depicted example synchronous dynamic amplifier 1 includes a dynamic oscillator power circuit 2, an information signal generator 4 generating a signal IN(t), and an example load, or power dissipation element, 6. FIG. 1 labels the load 6 separate from the dynamic oscillator power circuit 2. However, as one of ordinary skill in the pertinent arts will understand upon reading the entirety of this description and its accompanying figures, the load 6 may, for some embodiments, operate as a portion of the circuit 2. The voltage appearing on the load 6 is labeled Vout(t).

The FIG. 1 example further includes a power supply 8, for delivering power PWR to the PIN terminal of the dynamic oscillator power circuit 2. The PIN terminal is a representative label for the connections from which physical elements of the dynamic oscillator power circuit 2 receive power, and is not limited to being a single physical element or terminal of the dynamic oscillator power circuit 2. With continuing reference to FIG. 1, the dynamic oscillator power circuit 2 has an input terminal S1 for receiving the signal IN(t). The S1 terminal connects to at least one of the circuit elements, examples of which are described in further detail, of the dynamic oscillator power circuit 2.

The dynamic oscillator power circuit 2 is an electrical circuit constructed and arranged to oscillate when powered by the power supply 8, in the absence of a signal IN(t), according to a predetermined chaotic system dynamic D(t), where t represents time, and D(t) is a vector defining the state of the circuit 2. An illustrative example is a Rossler type chaotic system dynamic.

FIG. 1 further includes an optional adaptive power control and output stabilization circuit 10 which generates a control signal cs(t). Later described embodiment of the chaotic oscillator 2 include voltage controlled elements receiving cs(t). As will be described the cs(t) adjusts the system dynamic D_{A}(t) in accordance with the envelope of the input signal IN(t), for increasing amplific-efficiency.

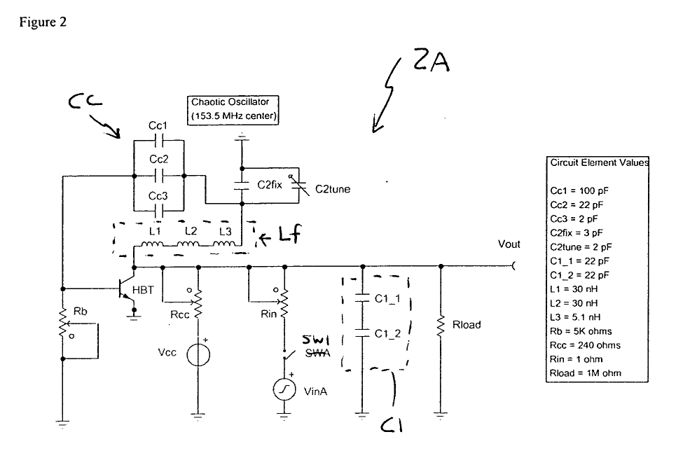

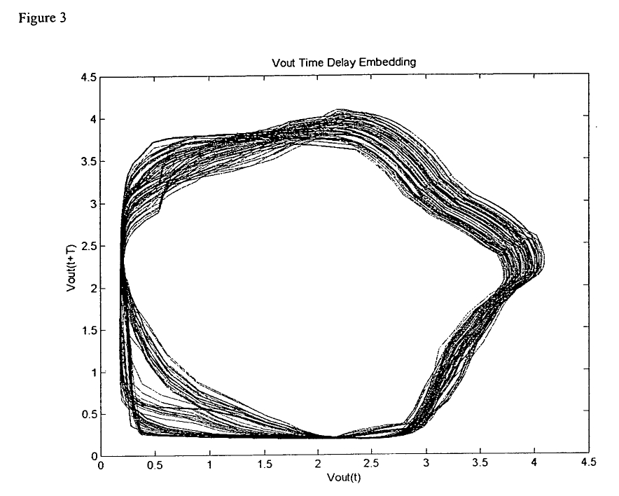

FIG. 2 shows a schematic diagram 2A of an example of the FIG. 1 dynamic oscillator power circuit 2. The FIG. 2 example circuit 2A generates a corresponding example non-synchronized system dynamic oscillation D(t), and a two-dimensional projection, labeled D_{A}(t), of the example generated by the FIG. 2 circuit 2A is shown on FIG. 3.

The example circuit 2A is based on a Colpitts oscillator, with component values and voltage biases selected to obtain the FIG. 3 chaotic system dynamic D_{A}(t). The FIG. 3 system dynamic D_{A}(t) has an orbital frequency of approximately 150 MHz.

The FIG. 2 example dynamic power oscillator 2A was selected to be a Colpitts-based circuit only for purposes of an illustrative example, to assist persons of skill in the relevant arts to understand and replicate an amplifier according to this description. The Colpitts configuration was selected because it is well known, is easily modeled, can be implemented as a simple circuit, and is scaleable in frequency. Further, the chaotic dynamics produced by a Colpitts oscillator are well understood.

Parameter values for the FIG. 2 circuit 2A to generate chaotic oscillations of a Rossler type are easily determined. An example set is shown in Table 1 below. A different parameter value, or varying one or more parameter values, yields different degrees of chaotic behavior, and the changes are well understood. As will be further described, varying the parameter values provides tuning and optimization of performance for specific applications, including those requiring adaptation to varying signal conditions.

For consistency in referencing, the term “chaotic system dynamic” and the reference label D(t) will be used to identify the free-running oscillation of the circuit 2 in the absence of a signal IN(t). The term “absence” includes both a zero valued signal IN(t) and an open state of a switch, if any, for selectively opening and closing an electrical path from the information signal generator 4 and the S1 input of the dynamic oscillator power circuit 2. The FIG. 2 example of the circuit 2 shows such a switch as SW1.

Referring to FIG. 2, the depicted example circuit 2A is formed of a single heterojunction bipolar transistor HBT, with a collector bias resistor Rcc connected to the power supply Vcc. An LC-type feedback path from the HBT collector to the HBT base is formed by the inductor Lf and capacitor CC. The FIG. 2 depiction of the example circuit 2A shows Lf as three inductors, L1, L2, and L3, connected in series, and the capacitor CC as three capacitors, CC1, CC2 and CC3 connected in parallel. This depiction of Lf and CC is based on availability of off-the-shelf components, as FIG. 2 is based on a SPICE model of a particular constructed and tested prototype. The actual inductors and capacitors used for the prototype were off-the-shelf values and, therefore, the selected values of Lf and CC required the depicted arrangement.

With continuing reference to FIG. 2, a bias resistor Rb connects from the base of HBT to ground. The example bias resistor Rb of the FIG. 2 circuit 2A is shown variable, which represents a prototype hardware construction.

A C2 capacitance connects from the junction of CC and Lf to ground. FIG. 2 shows the example circuit 2A capacitance C2 as a parallel connection of C2fix and C2tune. The parallel connection obtains the desired total capacitance, largely established by C2fix, with C2tune providing a range of fine-tuning or adjustment. The adjustment provided by the example circuit 2A capacitor C2tune provides an optional feature, described in further detail, of tuning the system dynamic D_{A}(t) in accordance with a running average, AvgErr(t) of the difference between Vout(t) and IN(t).

The voltage of Vcc depends on the required amplitude of Vout(t), and the biasing requirements for the transistor HBT. As described in further detail, the chaotic system dynamic D(t), including the FIG. 3 example D_{A}(t) results from the transistors, such as HBT, operating in a non-linear mode during the D_{A}(t) oscillation cycles. The transistors, such as HBT of the FIG. 2 circuit 2A, operating in a non-linear mode provides a very large increase in efficiency of the FIG. 1 circuit in amplifying an IN(t) signal when compared to a conventional transistor-based amplifier performing the same amount of amplification. Persons skilled in the electronic amplifier arts can, in view of this description and the example circuit 2A of FIG. 2 and its example chaotic system dynamic D_{A}(t) of FIG. 3, readily select the appropriate Vcc value. An example Vcc, corresponding to the Table I values for the FIG. 2 circuit, is 3 volts.

With continuing reference to FIG. 2, the example dynamic oscillator power circuit 2A includes a variable coupling resistor Rin having its wiper terminal connected to the collector of the HBT transistor, and one end connected to an open-close isolation switch SWA. A capacitance C1 connects from the collector of HBT to ground. FIG. 2 shows the capacitance C1 as a series connection of C1_1 and C1_2 to conform to the particular constructed prototype. C1 may be implemented as a single capacitor.

FIG. 2 shows an example resistor Rload, which is a specific example of the FIG. 1 load 6, as external to the dynamic oscillator power circuit 2A. However, the depiction of Rload as external to the circuit 2A is only for purposes of labeling the functions of the illustrated circuits. The Rload resistance is a variable in the equations defining the Colpitts-type oscillator operation of the FIG. 2 circuit 2A. Further, as will be understood upon reading this description, in many applications of the described dynamic oscillator-based amplifier of FIG. 1, load 6 will be reactive. An illustrative example is the load 6 being an antenna such as, for example, an antenna for a cellular telephone (not shown in FIG. 1 or 2). If load 6 is reactive the reactance will, in general, act as part of the circuit 2 because the reactance will, depending on the topology of the circuit 2, contribute to the NFreq and the natural system dynamic D_{A}(t). This is a further novel feature of the described subject matter. For example, in reference to the particular FIG. 2 circuit 2A, if Rload were replaced by an antenna or other reactive load, an NFreq of 150 MHz is readily obtained by modifying the value of one or more of CC, C2 and Lf.

Table I below shows an example set of component values for the FIG. 2 circuit 2A:

TABLE 1

| | | |
|---|---|---|
| CC1 | 100 | pF |
| CC2 | 22 | pF |
| CC3 | 2 | pF |
| C2fix | 3 | pF |
| C2tune | 2 | pF |
| C1_1 | 22 | pF |
| C1_2 | 22 | pF |
| L1 | 30 | nH |
| L2 | 30 | nH |
| L3 | 5.1 | nH |
| Rb | 5K | ohms |
| Rcc | 240 | ohms |

An example Rin resistor value for use with the Table 1 component values is 1 ohm, and an example Rload is 1 M ohm. An example transistor HBT is a Sirenza SGA SiGe HBT, which is an NPN-type heterojunction bipolar transistor available from a number of commercial vendors.

FIG. 3 shows a two-dimensional projection of a simulated dynamic oscillation D_{A}(t), generated by a computer model of the FIG. 2 example dynamic oscillator power circuit 2A. The basis vectors for the FIG. 3 D_{A}(t) are the collector voltage, labeled Vout, of the FIG. 2 transistor HBT at time t and the collector voltage or Vout at time t+T, where T=, for example, 3.3 ns, which is approximately the average cycle time. Time delay embedding is a method of producing an n-dimensional representation of the state space attractor of a single, time-dependent chaotic oscillation. For a two-dimensional projection, the original time oscillation is plotted versus a copy of itself delayed in time by T. It has been shown that a proper time-delay embedding can re-construct the state-space attractor of a chaotic system to within a simple coordinate transformation.

The FIG. 3 simulated D_{A}(t) is based on the switch SW1 being open, meaning that the FIG. 2 circuit is free-running, non-synchronous with respect to IN(t). The modeling program used for generating FIG. 3 from the FIG. 2 circuit was built using the well-known PC-based software mathematical and circuit emulation tools Matlab® and PV-Wave®, using the known software language C++.

FIG. 3 is a specific example, depicting D_{A}(t) as a two-dimensional projection using two values to represent the state of the FIG. 2 circuit 2A. In a general sense, the state vector D(t) of the dynamic oscillator power circuit 2 may be represented as [d1(t), d2(t) . . . dN(t)], with each di(t) being a voltage across and/or a current through a respective one of such circuit elements employed in the particular implementation of circuit 2, at a given time t. The parameter N is for purposes of reference and is not limited to being a number of circuit elements. Further, state values, such as di(t) and dj(t), may be defined as d(t) and d(t+T), respectively, where d(t) is a voltage across or current through a respective one or more elements of circuit 2 at time t and d(t+T) is a respective voltage across or current through the same one or more elements at time t plus T.

Referring to FIG. 1, the output Vout(t) is typically, but is not limited to being, one of the state values di(t) of the state vector D(t).

As identified above in reference to FIG. 1, the dynamic power oscillator circuit 2 includes at least one coupling element (not shown in FIG. 1), connected to S1 for receiving the input signal IN(t). The FIG. 2 example 2A of the FIG. 1 dynamic oscillator power circuit 2 embodies the coupling element as a low-valued resistor Rin connecting to, in the depicted example, the collector of the FIG. 2 heterojunction bipolar transistor HBT. The collector of the FIG. 2 HBT is also the Vout(t) signal.

An example operation of the FIG. 1 synchronous dynamic amplifier 1 will now be described.

When IN(t) is received by the dynamic oscillator power circuit 2, it acts on, or through, the circuit's coupling element to perturb the circuit 2 from its free running chaotic oscillation D(t). The perturbation will be described in reference to the FIG. 3 example. As depicted by FIG. 3, the free running trajectory D_{A}(t) is according to a plurality of bands (not individually labeled), forming a deterministic, chaotic, trajectory about a particular attractor. The perturbation applied by the signal IN(t) nudges or pushes the state D_{A}(t) from one segment, or band, of the trajectory inward or outward to another and then to another and so on.

The effect of the perturbation can be understood, or analyzed, by characterizing the trajectory D_{A}(t) as including, somewhere along its infinite path, substantially every waveform segment, both in form and duration, that can exist. Therefore, if an arbitrary segment of IN(t), for t=t₁ to t₂, is selected, a position along the D_{A}(t) trajectory can be found from which, for at least the time duration t₁ to t₂, D_{A}(t) will match, or closely approximate IN(t). This position on D_{A}(t) is called the position which “sources” a signal identical to, or approximating, IN(t), for t_{1 to t}₂.

Referring again to FIG. 3, the position along D_{A}(t) defines Vout(t). The coupling element is realized in the FIG. 2 circuit 2A as the resistor Rin connected to the collector of HBT. The collector of HBT is one of the state vectors of D_{A}(t), and is also Vout(t). Therefore, by IN(t) pushing the state vector D_{A}(t) to a position on FIG. 3 sourcing IN(t) it also pushes D_{A}(t) to a position sourcing a Vout(t) that matches, or closely approximates IN(t). The collector voltage of HBT, though, delivers power through the FIG. 2 load Rload. Therefore, as IN(t) perturbs, or nudges, or pushes, the FIG. 3 state vector D_{A}(t) from one band inward or outward to another, it causes a power of Vout(t) squared divided by Rload to be dissipated. The power required for IN(t) to perform the perturbation of the FIG. 2 circuit 2A is very low. Power Added Efficiency (PAE) values and gain values obtained with prototypes will be described.

Referring to FIGS. 1-3, a fundamental aspect and novelty of the described circuit 2 is that IN(t), acting through the coupling element, perturbs the oscillation D(t) through a time history of positions, sourcing segments of its FIG. 3 natural chaotic trajectory. The segments are sourced such that Vout(t) has approximately the waveform of IN(t).

A fact at least as significant as power gain is that the transistor HBT is in its non-linear mode while IN(t), acting through Rin, perturbs the state vector D_{A}(t) to locations of the FIG. 3 trajectory sourcing IN(t). Stated differently, IN(t) perturbs the FIG. 2 circuit 2A to a history of positions where the non-linear operation of HBT sources a history of signals Vout(t) matching or approximating IN(t). Therefore HBT, even though operating in its non-linear region as the circuit 2A is perturbed about the FIG. 3 state space, effects an output Vout(t) that is nearly linear with respect to IN(t). This is a novel and fundamental feature of the synchronous dynamic amplifier. The power dissipated by, or lost from, HBT for a given power delivered to Rload is markedly lower when HBT is in its non-linear region. Further, the power required of IN(t) to perturb the circuit 2 to source Vout(t) substantially matching IN(t) is very low.

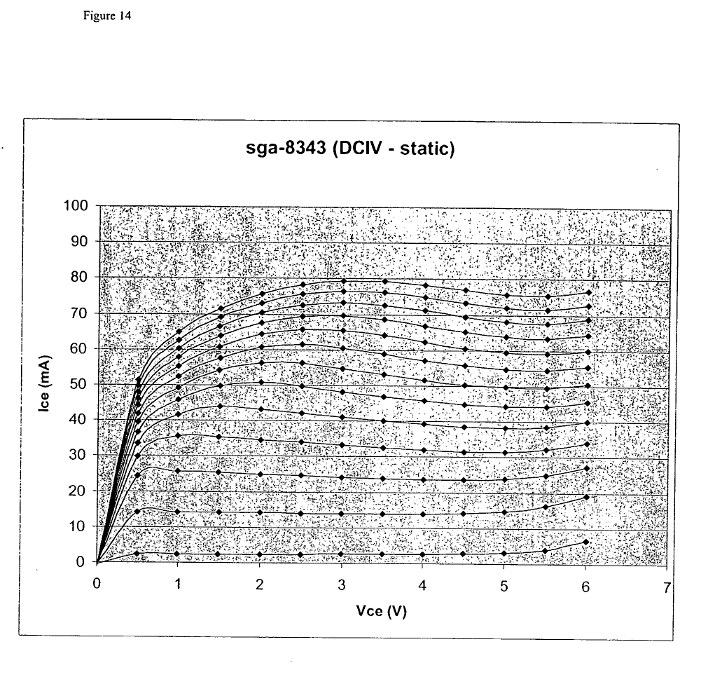

Therefore, the PAE of the example FIG. 2 amplifier, and of any other synchronous dynamic amplifier as shown, for example, by FIG. 1, is markedly higher than the PAE of a conventional transistor amplifier. For example, computer simulations and prototype testing of the FIG. 14 version of the FIG. 1 synchronous dynamic amplifier, using a 2 MHz Colpitts-based oscillator similar to the FIG. 2 circuit 2A, shows gains up to 55 dB and PAE ranging up to 80%.

The available technologies, and the criteria for selecting which technology to use for the dynamic oscillator power circuit 2 are the same as those applied by persons skilled in the art of conventional amplifier design. With respect to selection of technology, the conventional criteria are well known and include, for example, operating frequency, power dissipation, size/weight requirements, operating environment, and cost.

Referring to the FIG. 2 circuit 2A, the 150 MHz non-synchronous dynamic oscillation frequency NFreq is readily implemented, complete with all depicted components, as an analog integrated circuit (IC). The frequency bands at which IC technology may be used are known and, for example, if the FIG. 2 circuit 2A is modified to have a frequency NFreq such as, for example, approximately 1 GHz, the implementation as an analog IC is straightforward, using known design methods.

Depending on the NFreq and on design choice, a portion of the dynamic oscillator power circuit 2, such as the example FIG. 2 circuit 2A, may be implemented as an analog IC, with provision, via conventional input/output terminals, for using external components for one or more of the circuit components. Other technologies contemplated for implementing the FIG. 1 circuit 2, such as the example FIG. 2 circuit 2A, include discrete conventional components assembled using known printed circuit board (PCB) technology.

Technologies for implementing the varactor C2tune are known. For example, referring to FIG. 2, if PCB technology is used, the varactor C2tune may, for example, be a discrete component readily available, as an off-the-shelf item, from numerous commercial vendors. As another example, if the power chaotic circuit 2, such as the FIG. 2 example 2A, is implemented as an IC, the varactor C2tune may be implemented as in Barium Strontium Titanate (BST) ferroelectric thin file technology, which is known in the art. Other known technologies for implementing a varactor, such as C2tune, suitable for use in constructing a dynamic oscillator power circuit 2 according to this description, can be readily selected by one skilled in the pertinent arts.

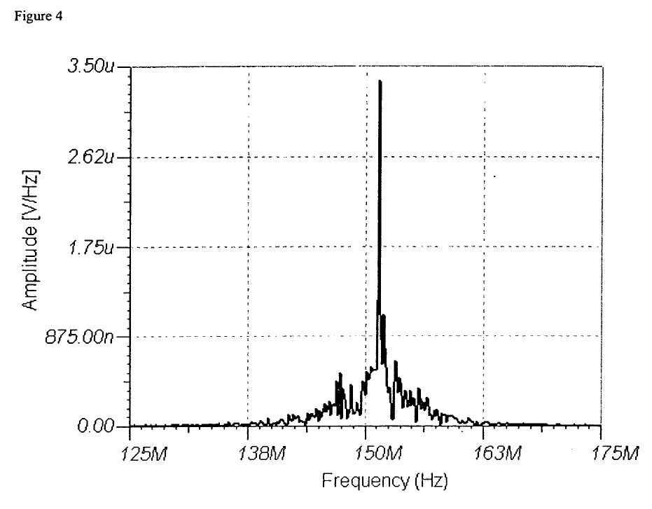

FIG. 4 shows the frequency spectrum of the Vout (t) component of the FIG. 3 dynamic oscillation D_{A}(t), illustrating the broad frequency content indicative of chaotic behavior. As illustrated, the center frequency of the FIG. 4 frequency spectrum is approximately 150 MHz.

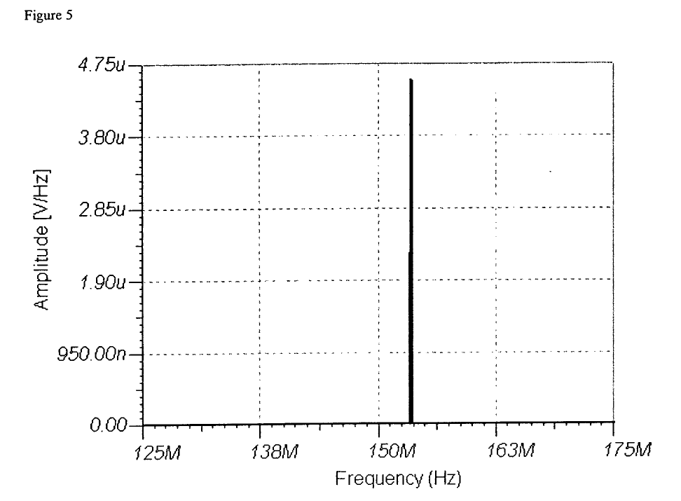

FIG. 5 shows the frequency spectrum of the Vout(t) component when switch SWA is closed and a 150 MHz sine wave is the IN(t) connected to the FIG. 2 Rin resistor.

Referring to FIG. 5, it is seen that the Vout(t) is a substantially pure 150 MHz sine wave, tracking or matching the example 150 MHz input IN(t). The FIG. 5 Vout(t) is the output to the FIG. 2 Rload sourced by the circuit 2A being perturbed by the 150 MHz IN(t), while HBT is in a substantially nonlinear mode of operation. As can be seen, Vout(t) is a substantially pure sine wave, sourced by the circuit 2A and the transistor HBT in a non-linear mode in response to perturbation by IN(t). Further, although HBT is in a nonlinear mode, there are no substantial harmonics seen in Vout(t). This is a substantial novel feature of this described subject matter, which is markedly different from the operation of, and from the operational state of transistors in, conventional transistor amplifiers.

The Rin resistor is not necessary for all implementations in accordance with this description. A non-zero Rin is shown to enable defining an Err(t) value, which is a difference between the IN(t) value and a component of the dynamic oscillator circuit state D(t) while the IN(t) is coupled to the circuit 2. For example, referring to the FIG. 2 circuit 2A, an example Err(t) is the difference between the input IN(t) and the Vout(t) while the switch SW1 is closed. Further described examples detect and utilize Err(t) as a control signal for varying the tuning capacitor C2tune, thereby minimizing Err(t).

Referring to FIG. 2 and 3, C2tune is one of the component values defining the FIG. 3 example non-synchronous dynamic D_{A}(t). Changing C2tune changes D_{A}(t) in that it changes the amplitude Vout(t) and Vout(t+T). This in turn changes the “volume” of D_{A}(t), where “volume” is the three (or more) dimensional region enclosed by the surface of D(t). This is represented, in part, by the area enclosed by the two-dimensional projection represented by the FIG. 3. This phenomenon of changing the volume of D(t) is not limited to the FIG. 2 example circuit 2A, or to the imbedded dynamic depicted by FIG. 3.

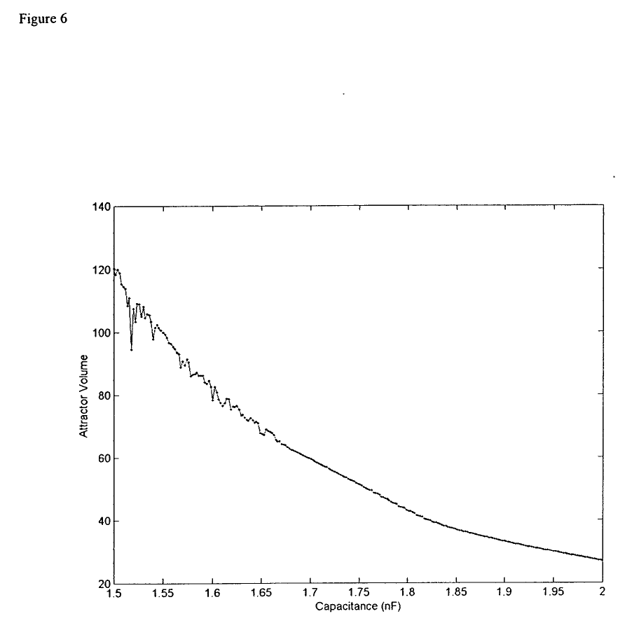

FIG. 6 depicts a variation of the FIG. 3 attractor volume as the capacitor C2tune of the FIG. 2 circuit is changed. A range of C2tune values that yields a corresponding range of non-synchronous dynamics D_{A}(t), each exhibiting Rossler behavior, but with larger or smaller volumes, is readily identified by plugging values for C2tune into the computer model of, for example, the FIG. 2 circuit 2A. The FIG. 2 example circuit 2A is a Colpitts type dynamic oscillator 2, and therefore determining the range of C2tune for generating a desired range of non-synchronous dynamics D_{A}(t), with a corresponding range of volumes, is very easy to perform.

Referring to FIGS. 2 and 3, the range of volumes for the non-synchronous dynamic D_{A}(t) that C2tune must, preferably, obtain is determined, or at least sufficiently approximated, by the range of magnitude of the input information signal IN(t). The reason is that, as described above, the synchronous dynamic amplifier operates by IN(t) causing a running perturbation of the circuit 2 so that it sources a Vout(t) having approximately the same waveform as the input signal IN(t). For optimum PAE, the Vout(t) preferably has not only the same waveform as IN(t), but the same amplitude. This generally minimizes the power required of IN(t) to act through the coupling element to source Vout(t), and helps assure that the transistor, such as HBT of FIG. 2, is in its non-linear operating region.

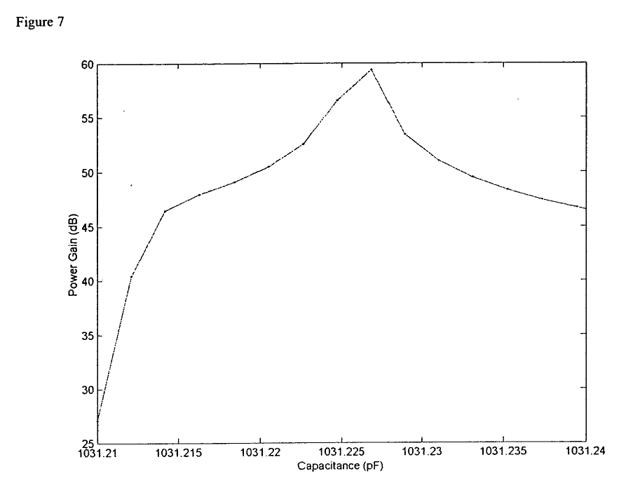

FIG. 7 illustrates a relation of power gain of the FIG. 1 synchronous dynamic amplifier, using the FIG. 2 example chaotic oscillator power circuit 2A with respect to change of a tuning capacitance C2tune.

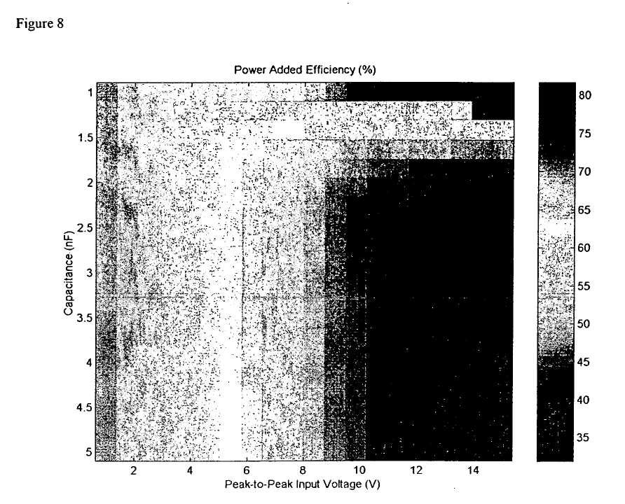

FIG. 8 shows a surface map illustrating the PAE of the example synchronous dynamic amplifier of FIG. 2 for a range of peak-to-peak IN(t) input voltages and a range of C2tune values.

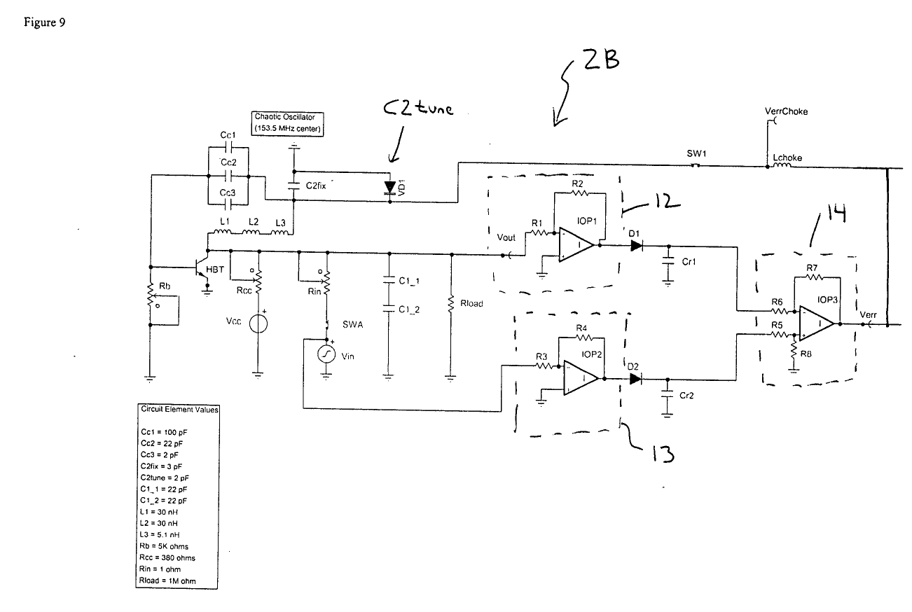

FIG. 9 shows an example circuit 2B, based on the FIG. 2 circuit 2A, including an example circuit embodiment of the adaptive power control and output stabilization circuit 10 of FIG. 1, for automatically maximizing the PAE over a range of IN(t) envelopes. The FIG. 9 example circuit 2B includes, for purposes of comparison, all components of the FIG. 2 circuit 2A, and these are labeled identically in the respective figures.

Referring to FIG. 9, the circuit 2B includes as the example implementation or embodiment of the FIG. 1 circuit 10, a first envelope detector 12 for generating EV(IN(t)), which is the average of the envelope of IN(t), and a second envelope detector 14 for generating EV(Vout(t)), which is the average of the envelope of Vout(t). The FIG. 9 implementation of the FIG. 1 circuit 10 further includes a difference circuit 16 generating AvgErr(t), which is a scaled difference of EV(IN(t)) and EV(Vout(t)). AvgErr(t) passes through a choke Lchoke to generate the control signal CS(t), which controls the varactor VD1. VD1 corresponds to the C2tune capacitor of FIG. 2. The capacitance of VD1, i.e., C2tune, is preferably linear and, therefore, CS(t) adjusts VD1, or C2tune, to automatically drive AvgErr(t) to its minimum value. The range of C2tune and of CS(t) is readily determined by SPICE modeling over a predetermined range of the envelope magnitude of IN(t).

The FIG. 9 example first envelope detector 12 is formed of an operational amplifier IOP1, gain and impedance resistors R3 and R4, a diode D2 and a capacitor Cr2. Likewise, the FIG. 9 example second envelope detector 14 is formed of an operational amplifier IOP1, gain and impedance resistors R1 and R2, a diode D1 and a capacitor Cr1. The operational amplifiers IOP1 and IOP2, the R1, R2 R3, R4, D1, D2, Cr1 and Cr2 components may be a commercially available units or can be implemented within an integrated circuit chip with the remainder of the FIG. 9 circuit. Envelope detectors and their hardware implementations are well-known in the electronic arts and, therefore, further description of 12 and 14 is omitted as unnecessary for one of ordinary skill to understand or use the FIG. 9 circuit, or to construct variations of same in accordance with this description.

The FIG. 9 difference circuit 16 is formed of an operational amplifier IOP3, with gain and impedance-setting resistors R5, R6, R7 and R8, in accordance with known difference amplifier implementations.

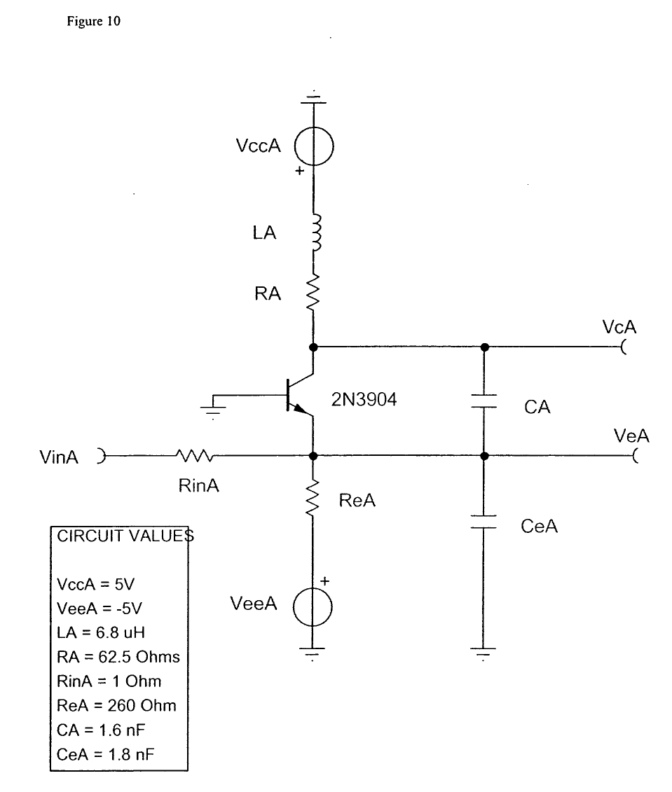

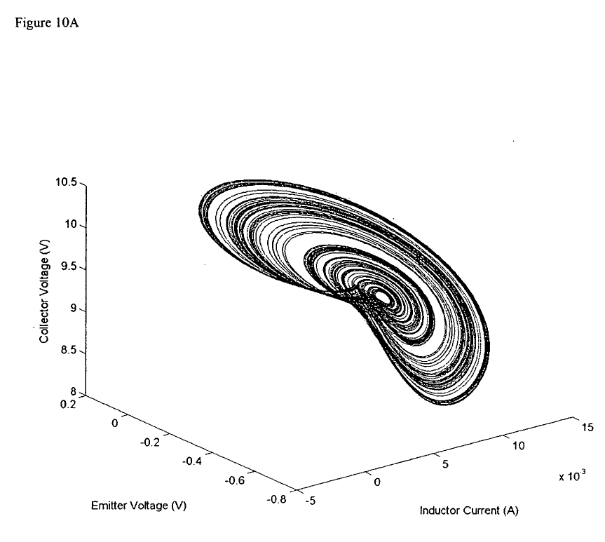

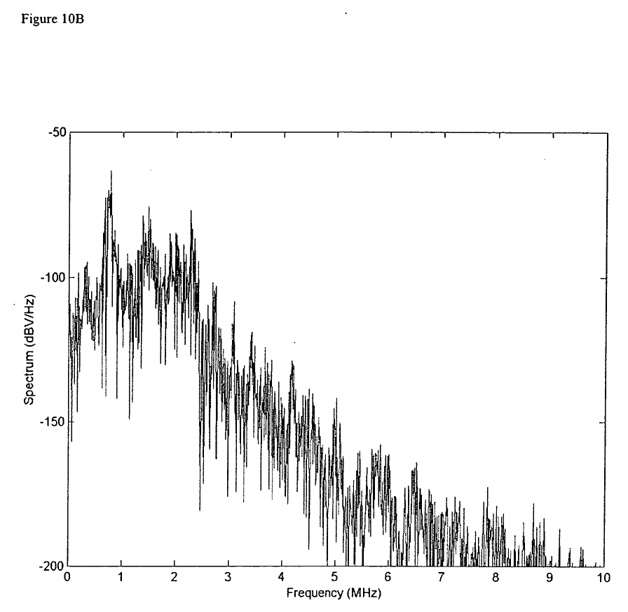

FIG. 10 shows another example of the FIG. 1 dynamic oscillator circuit 2, labeled 2C. The FIG. 10 circuit 2C is similar to the FIG. 2 circuit 2A, as it is based on a Colpitts oscillator, but has a non-synchronous oscillating frequency Nfreq of approximately 2 MHz. TABLE II shows example values for each of the FIG. 10 circuit components.

TABLE II

| | | |
|---|---|---|
| VccA | 5 | V |
| VeeA | −5 | V |
| LA | 6.8 | uH |
| RA | 62.5 | Ohms |
| RinA | 1 | Ohm |
| ReA | 260 | Ohm |
| CA | 1.6 | nF |
| CeA | 1.8 | nF |

FIG. 10A shows a two-dimensional projection of the chaotic oscillation exhibited by the FIG. 10 circuit. FIG. 10B shows the frequency spectrum of the emitter voltage of the FIG. 10 synchronous dynamic amplifier in free-running oscillation.

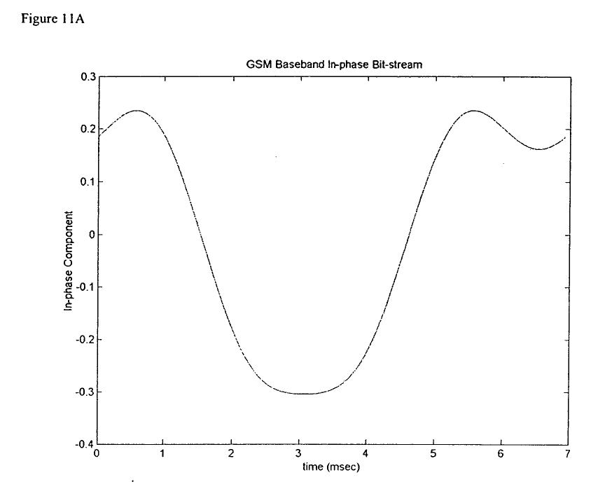

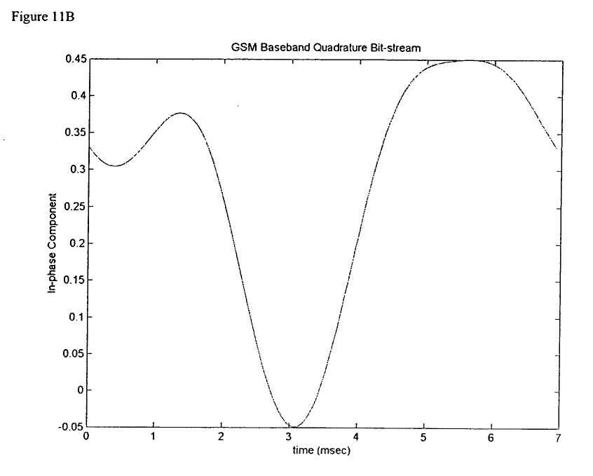

FIGS. 11A through 11D show an example of the FIG. 1 generic information signal IN(t), labeled IN1(t). The FIG. 11A-11D example signal IN1(t) is a standard GSIM signal used by cell phones in the United States and elsewhere. FIGS. 11A and 11B depict, respectively, the in-phase and quadrature baseband components of IN1(t). FIG. 11C depicts the modulated carrier, and FIG. 11D depicts the power spectrum.

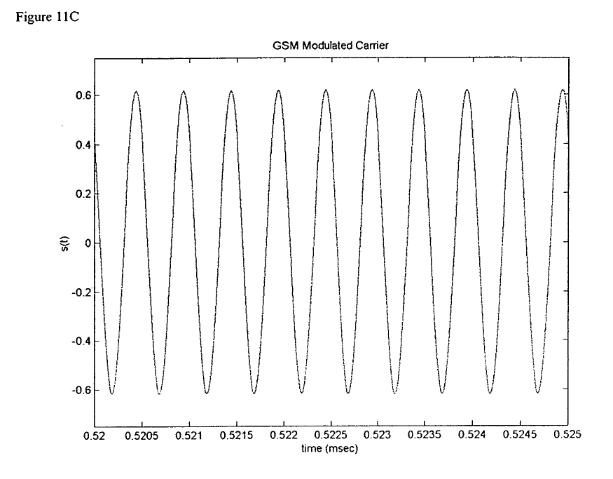

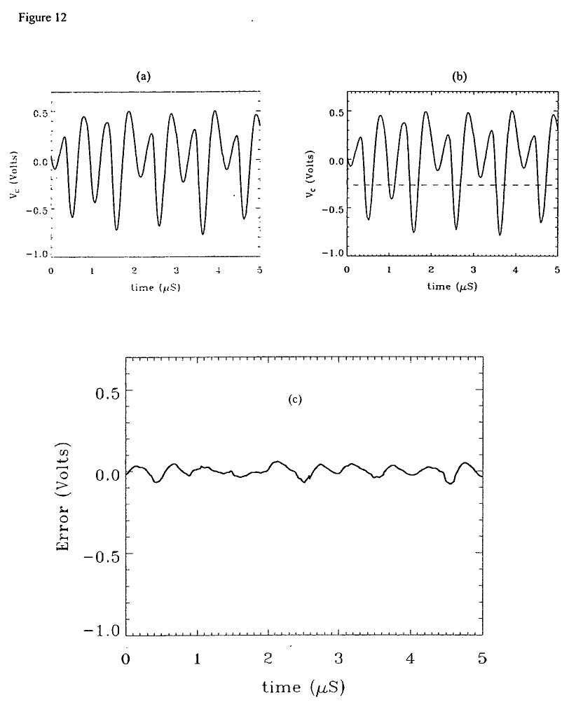

FIG. 12A graphically depicts a computer-generated simulation of a GSIM signal input as IN(t) to a computer model of the linear-transfer chaotic amplifier circuit of FIG. 10. FIG. 12B shows the computer simulation results of the amplified output signal OUT(t) appearing on the load 6 of the modelled FIG. 10 circuit. FIG. 12C shows the computer simulation of the error signal ERR(t), which is equal, for this example, to OUT(t)−INT(t). As can be seen, the OUT(t) signal tracks very close to IN(t). Computer simulation showed the power gain to be well over 60dB and the power added efficiency over 72%

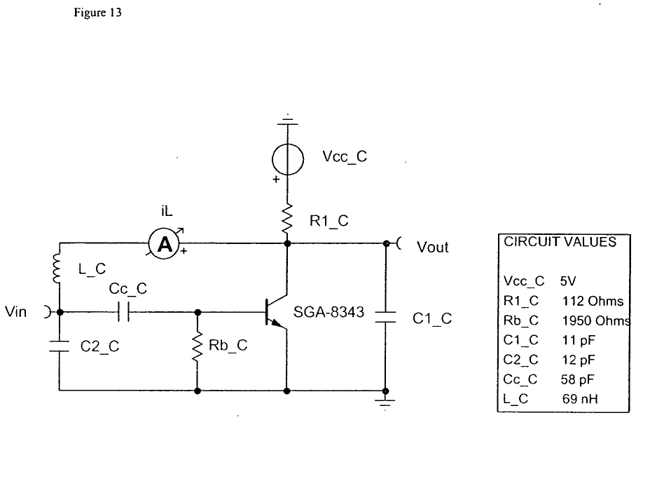

FIG. 13 shows a schematic diagram of an 850 MHz example high frequency, Colpitts type, chaotic power oscillator. TABLE Ill shows example values for each of the FIG. 13 circuit components.

TABLE III

| | | |
|---|---|---|
| Vcc_C | 5 | V |
| R1_C | 112 | Ohms |
| Rb_C | 1950 | Ohms |
| C1_C | 11 | pF |
| C2_C | 12 | pF |
| Cc_C | 58 | pF |
| L_C | 69 | nH |

FIG. 14 shows the DC I-V characteristics for the example high-frequency HBT used to model the FIG. 11 850 MHz circuit.

While the present invention has been disclosed with reference to certain preferred embodiments, these are for purposes of example, and should not be understood as limiting the scope of the embodiments, aspects, and implementations that one of ordinary skill in the pertinent arts can construct and use based on this description. For example, referring to FIG. 1, the information signal generator 4 is substantially generic, as neither the technology nor architecture of, nor the specific waveform of, the information signal IN(t) generated by the source signal generator 4 need to be particularly selected or constructed for the amplifier circuits described by this disclosure. The information signal generator 4 is, for example, a conventional BPSK, QPSK, QAM, FSK, continuous analog FM signal generator, or substantially any other known type of information-carrying signal generator known in the telecommunications arts. Further, the FIG. 3 characteristic system dynamic D_{A}(t) corresponds to the FIG. 2 example power chaotic circuit 2A, and is for purposes of example only. Other characteristic system dynamics D(t) can be selected, and circuits 2 can be constructed having the selected dynamic, by straightforward application of available literature describing chaotic circuits and using known circuit modeling software packages such as, for example, SPICE™.

One skilled in the pertinent arts will recognize that these and other variations of, and additional combinations of, these embodiments and implementations can be readily constructed and used, each falling within the scope of the claims set forth below.

1. A method for amplifying a signal, comprising:
providing a chaotic oscillator;
providing an information signal having a first waveform;
generating an output signal having a second waveform corresponding to the first waveform of said information signal by synchronizing an oscillation of said chaotic circuit to the information signal.

2. A method according to claim 1 wherein the providing a chaotic oscillator includes providing a load, and wherein the synchronizing an oscillation of said chaotic circuit to the information signal includes the chaotic circuit receiving a power having a first average power value from said information signal, and wherein said output signal dissipates a power in the load having a second average power value substantially greater than said first average power value, such that said output signal is a power amplification of said information signal.

3. A method according to claim 1 wherein the information signal has a non-chaotic first waveform, and the second waveform is non-chaotic corresponding to the first waveform.

4. A method for amplifying a signal, comprising:
generating an output signal having a chaotic trajectory about an attractor, the generating including powering a chaotic circuit;
providing an information signal having a first waveform;
generating an output signal having a second waveform corresponding to the first waveform of said information signal by coupling the information signal to the chaotic circuit in a manner synchronizing the output signal to the information signal.

5. A method according to claim 4, wherein the trajectory has a two dimensional projection, in a plane formed of a first axis representing a first state of the chaotic oscillator circuit and a second axis representing a second state of chaotic oscillator circuit, and the trajectory includes a plurality of bands in said plane, and wherein the synchronizing includes coupling the information signal to the chaotic circuit in a manner perturbing the output signal inward and outward among the bands.

6. A method according to claim 5, wherein the perturbing pushes the output signal to a history of locations on the bands which source the output signal to have the second waveform correspond to the input signal first waveform.

7. A method according to claim 1 wherein the chaotic oscillator includes a transistor having a V-I characteristic having a non-linear region and wherein said transistor is in said non-linear region for at least a portion of the time of said generating an output signal.

8. A method according to claim 4 wherein the chaotic oscillator includes a transistor having a V-I characteristic having a non-linear region and wherein said transistor is in said non-linear region for at least a portion of the average time of said generating an output signal.

9. A method according to claim 2 wherein the information signal first waveform is at least one from among the group consisting of {AM, FM, PM, BPSK, QPSK, and QAM}.

10. A method according to claim 9 wherein the chaotic oscillator includes a transistor having a V-I characteristic having a non-linear region and wherein said transistor is in said non-linear region for at least a portion of the average time of said generating said output signal as a power amplification of said information signal.

11. A method according to claim 6, wherein the chaotic oscillator includes a transistor having a V-I characteristic having a non-linear region, and wherein the information signal has a non-chaotic first waveform, and wherein said transistor is in said non-linear region for at least a portion of the average time of said perturbing the output signal to a history of locations on the bands which source the output signal to have the second waveform correspond to the input signal first waveform.

12. A method according to claim 11 wherein the output signal is coupled to a load associated with said chaotic circuit, and wherein said perturbing of said chaotic circuit to a history of locations on the bands which source the output signal to have the second waveform correspond to the input signal first waveform includes the chaotic circuit receiving a power having a first average power value from said information signal, and wherein said output signal dissipates a power in the load having a second average power value substantially greater than said first average power value, such that said output signal is a power amplification of said information signal.

13. A method according to claim 5 wherein the information signal has a non-chaotic first waveform, and the second waveform is non-chaotic corresponding to the first waveform.

14. A method according to claim 5, wherein the information signal has a non-chaotic first waveform, and wherein the perturbing pushes the output signal to a history of locations on the bands which source the output signal to have the second waveform correspond to the input signal first waveform.

15. An amplifier comprising:
a chaotic oscillator including a coupling element, the coupling element having a terminal for receiving an external signal, and having an output terminal and a power terminal for receiving an external electrical power supply voltage, constructed and arranged such that in response to the power terminal receiving the external electrical power supply voltage concurrent with the terminal of the coupling element receiving a voltage below a predetermined threshold for a time duration exceeding a predetermined value an output voltage appears on the output terminal following a chaotic oscillation trajectory about an attractor,
wherein the power chaotic circuit is constructed and arranged such that, in response to the receiving terminal of the coupling element receiving an information signal, the output voltage is perturbed through a time history of states on or about the chaotic oscillation trajectory such that that the output voltage has a waveform in substantial accordance with the information signal.

16. An amplifier according to claim 15 wherein the power chaotic circuit further includes:
a voltage controlled capacitor having a control terminal; and
a varactor control circuit, the varactor control circuit having
a circuit for detecting a difference voltage, the difference voltage being the difference between the output voltage and the voltage delivered to the receiving terminal of the coupling element, and
a circuit for generating a varactor control signal in response to the detected difference voltage, the generating of the varactor control signal based on the detected difference in accordance to a predetermined mapping, the varactor control signal being connected to the control terminal of the voltage controlled capacitor, wherein
the predetermined mapping is such that an increase of the time average of the difference voltage generates a varactor control signal which changes the capacitance of the voltage controlled capacitor to a value which changes at least one of the chaotic oscillation trajectory and the attractor, the change being such that the time average of the difference voltage is reduced.

17. A radio transmitter comprising:
a power supply for delivering an electrical power supply output voltage;
a power chaotic circuit having a coupling element, the coupling element having a receiving terminal, and having a power terminal for receiving said electrical power supply voltage, constructed and arranged such that in response to the power terminal receiving said electrical power supply voltage concurrent with the receiving terminal of the coupling element receiving a voltage below a predetermined threshold for a time duration exceeding a predetermined value an output voltage appears on the output terminal following a chaotic oscillation trajectory about an attractor;
an antenna connected to the output terminal
wherein the power chaotic circuit is constructed and arranged such that in response to the receiving terminal of the coupling element receiving an information signal the output voltage is perturbed through a time history of states on or about the chaotic oscillation trajectory that the output voltage has a waveform substantially the same as the information signal.
